(19) United States
(12) Patent Application Publication
(10) Pub. No.: US 2016/0225801 A1
(43) Pub. Date: Aug. 4, 2016

(54) Method for Forming Hole Pattern and Method for Manufacturing TFT Display Using the Same

(71) Applicant: Hydis Technologies Co., Ltd., Gyeonggi-do (KR)

(72) Inventors: Seong-jung YUN, Gyeonggi-do (KR); Je-Geon YOO, Seoul (KR)

(21) Appl. No.: 15/008,705

(22) Filed: Jan. 28, 2016

(30) Foreign Application Priority Data
Jan. 30, 2015 (KR) 1020150015140

(51) Int. Cl. H01L 27/12; H01L 21/768; H01L 29/786; H01L 21/027

(52) U.S. Cl. CPC H01L 27/1288; H01L 21/0274; H01L 27/124; H01L 21/76802; H01L 29/78633

(57) ABSTRACT

Provided herein is a method for forming a hole pattern and a method for manufacturing a TFT display using the same, the hole pattern forming method including forming a light shield section above a substrate; applying a photoresist above the light shield section; downward light exposing of positioning a mask above the light shield section and then exposing the photoresist to light being emitted downwards from above the substrate; upward light exposing of exposing the photoresist to light being emitted upwards from below the substrate; and removing the photoresist not exposed to light at the downward light exposing and upward light exposing, thereby using the hole pattern forming method to manufacture a TFT display having improved opening rate and transmission rate.

### CROSS-REFERENCE TO RELATED APPLICATION

This application claims the benefit of priority under 35 U.S.C. §119(a) of Korean Patent Application No. 10-2015-0015140, filed on Jan. 30, 2015, in the Korean Intellectual Property Office, the entire disclosure of which is incorporated herein by reference for all purposes.

### BACKGROUND

1. Field

The following description relates to a method for forming a hole pattern and a method for manufacturing a TFT display using the same, and more particularly, to a hole pattern forming method capable of precisely controlling the position where the hole pattern is to be formed, and a method for manufacturing a TFT display having improved opening rate and transmission rate using the hole pattern forming method.

2. Description of Related Art

A conventional TFT display adopts a via hole pattern in order to connect a lower electrode that is below an upper insulating film with an electrode above the insulating film.

However, if a hole pattern is formed to be bigger than the lower electrode or if the hole pattern is formed horizontally outside the lower electrode due to an alignment error, in an etching process, an etching phenomenon may occur below the lower electrode, causing a defect in the pattern.

That is why a drain electrode 1 is formed to be bigger than a hole pattern 2 by as much as an error range (about 1-1.5 μm) in a TFT display, as illustrated in FIG. 1.

These days, the size of a unit pixel is becoming smaller, whereas drain electrodes must be expanded unnecessarily due to the reason mentioned above. Therefore, unnecessary expansion of a drain electrode is causing deterioration of the opening rate and transmission rate of a TFT display.

### SUMMARY

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A purpose of the present disclosure is to provide a hole pattern forming method capable of precisely controlling the position where the hole pattern is to be formed.

Another purpose of the present disclosure is to provide a hole pattern forming method capable of improving the alignment precision of the hole pattern by performing two steps of light exposure including a downward light exposing and an upward light exposing.

Another purpose of the present disclosure is to provide a hole pattern forming method wherein, in the upward light exposing process, a light shield section below a photoresist is used as a mask, thereby preventing the hole pattern from being formed horizontally beyond the range of the light shield section.

Another purpose of the present disclosure is to provide a method for manufacturing a TFT display wherein, in the process of forming a hole pattern above a drain electrode, the drain electrode is used as a mask, thereby preventing the hole pattern from being formed horizontally beyond the range of the drain electrode.

Another purpose of the present disclosure is to provide a method for manufacturing a TFT display wherein, above a drain electrode, a hole pattern may be formed having corners that exactly match some of the corners of the drain electrode.

Another purpose of the present disclosure is to provide a method for manufacturing a TFT display, wherein a drain electrode need not be expanded unnecessarily, thereby improving the opening rate and transmission rate.

The aforementioned purposes of the present disclosure and other purposes may all be accomplished by a method for forming a hole pattern and a method for manufacturing a TFT display using the same according the present disclosure.

According to an aspect, there is provided a method for manufacturing a TFT display, the method including forming a TFT above a substrate; applying a photoresist above the TFT; downward light exposing of positioning a mask above the TFT and then exposing the photoresist to light being emitted downwards from above the substrate; upward light exposing of exposing the photoresist to light being emitted upwards from below the substrate; and forming a hole pattern by removing the photoresist not exposed to light at the downward light exposing and upward light exposing.

The photoresist may be a negative type photoresist.

The upward light exposing may be performed before the downward light exposing.

The downward light exposing may be performed before the upward light exposing.

The upward light exposing and the downward light exposing may be performed simultaneously.

The mask may be positioned such that it horizontally overlaps with a portion of a drain electrode of the TFT.

The mask may be positioned such that it horizontally does not overlap with a gate electrode nor gate line.

The mask may be positioned such that, of data line direction boundaries of the drain electrode, a boundary not located above the gate electrode is horizontally within the mask.

The method for manufacturing a TFT display according to an embodiment of the present disclosure may further include forming a TFT insulating film above the TFT after the forming of a TFT and before the applying of a photoresist; and forming a via hole by etching the TFT insulating film exposed below the hole pattern after the forming of a hole pattern.

According to an aspect, there is provided a method for forming a hole pattern, the method including forming a light shield section above a substrate; applying a photoresist above the light shield section; downward light exposing of positioning a mask above the light shield section and then exposing the photoresist to light being emitted downwards from above the substrate; upward light exposing of exposing the photoresist to light being emitted upwards from below the substrate; and removing the photoresist not exposed to light at the downward light exposing and upward light exposing.

The mask may be positioned such that a partial boundary of the light shield section is horizontally within the mask.

The photoresist may be a negative type photoresist.

The upward light exposing may be performed before the downward light exposing.

The downward light exposing may be performed before the upward light exposing.

The upward light exposing and the downward light exposing may be performed simultaneously.

Various aforementioned aspects of the present disclosure has an effect of providing a hole pattern forming method capable of improving the alignment precision of the hole pattern by performing two steps of light exposure including an upward light exposing process and a downward light exposing process.

Furthermore, the present disclosure has an effect of providing a hole pattern forming method wherein a light shield section located below a photoresist is used as a mask in the upward light exposing process, thereby preventing the hole pattern from being formed horizontally beyond the range of the light shield section below.

Furthermore, the present disclosure has an effect of providing a method for manufacturing a TFT display wherein a drain electrode need not be expanded unnecessarily, thereby improving the opening rate and transmission rate.

Other features and aspects will be apparent from the following detailed description, the drawings, and the claims.

### BRIEF DESCRIPTION OF THE DRAWINGS

FIG. 1 is a plane view of a TFT display showing the relationship between a conventional hole pattern and a drain electrode;

FIGS. 2A-2D and 3A-3D are views illustrating a method for forming a hole pattern according to an embodiment of the present disclosure;

FIG. 4 is a plane view showing the relationship between a hole pattern and a light shield section formed by the hole pattern forming method of an embodiment of the present disclosure; and

FIGS. 5 to 19 are views illustrating a method for manufacturing a TFT display according to an embodiment of the present disclosure.

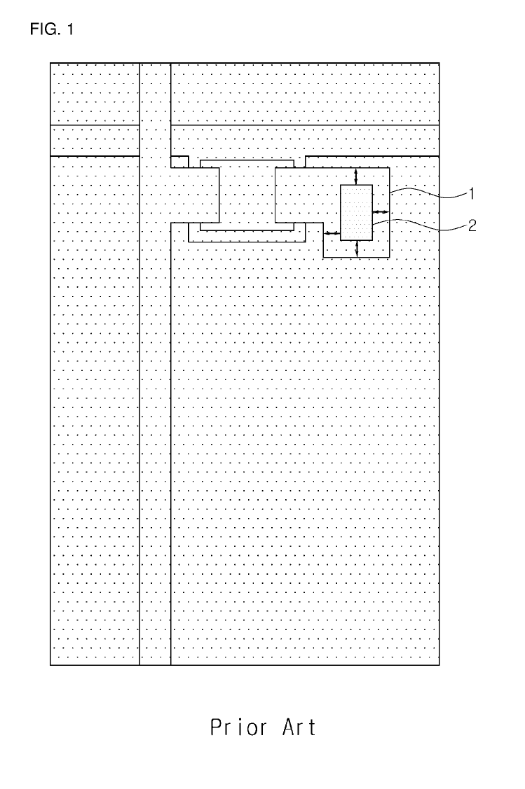

### DETAILED DESCRIPTION

Hereinafter, explanation will be made in detail on a method for forming a hole pattern according to the present disclosure and a method for manufacturing a TFT display using the same with reference to the drawings attached.

The following detailed description will include only the components necessary for those skilled in the art to understand a method for forming a hole pattern and a method for manufacturing a TFT display using the same according to the embodiments of the present disclosure, and explanation on other parts will be omitted so as not to obscure the essence of the present disclosure.

Furthermore, the terms and words used in this specification and the attached claims are not to be construed as being limited to general or lexical meanings, but are to be construed as meanings and concepts that are in line with the technical idea of the present disclosure so as to most appropriately describe the present disclosure.

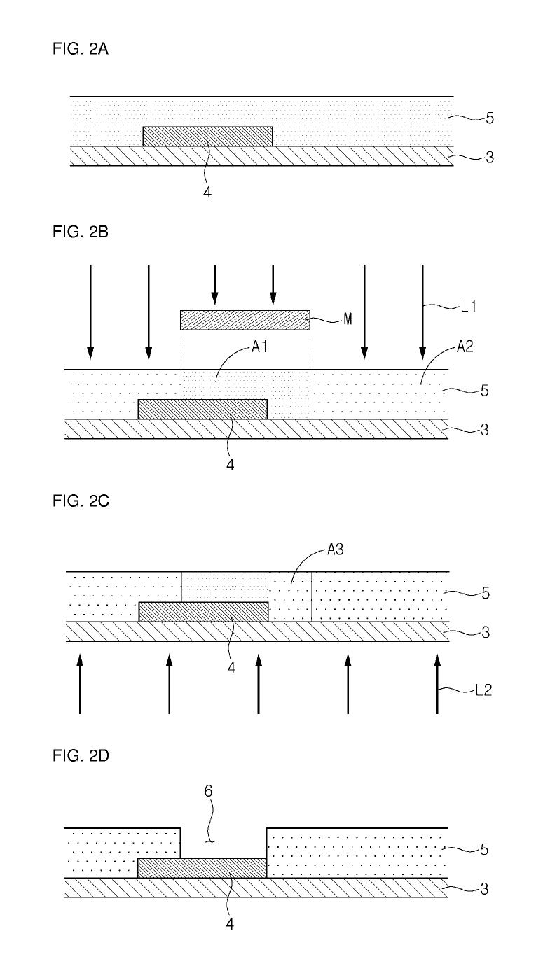

FIGS. 2A-2D illustrate a method for forming a hole pattern according to an embodiment of the present disclosure. The hole pattern forming method of this embodiment is a method using a lithography method.

Therefore, as illustrated in FIG. 2A, in order to form a hole pattern, a photoresist is applied above a substrate 3 provided with a light shield section 4.

Herein, the light shield section 4 may be any type of pattern made of a material that does not transmit light just as an electrode formed above the substrate 3.

Furthermore, preferably, the photoresist used herein may be a negative type photoresist that is hardened when exposed to light.

Then, when a mask M is positioned above the light shield section and the photoresist is exposed to light L1 being emitted downwards from above the substrate 3, only the area A1 shadowed by the mask is maintained in a non-hardened state, while the remaining area A2 is exposed to the light L1 and is thus hardened, as illustrated in FIG. 2B (downward light exposing step).

Then, when the photoresist is exposed to light L2 being emitted upwards from below the substrate 3 (upward light exposing step), as illustrated in FIG. 2C, of the area that had been maintained in a non-hardened state at the first light exposing step, the area A3 that does not overlap with the light shield section 4 is exposed to the light L2 and is thus hardened, while only the area overlapping with the light shield section remains non-hardened.

Then, when the photoresist is developed at this state, the non-hardened photoresist will be removed, and a hole pattern 6 will be formed above the light shield section as illustrated in FIG. 2D.

Although it is illustrated in the present embodiment that the photoresist 5 is applied right on top of the light shield section 4, an additional layer such as an insulating film may be formed between the light shield section 4 and the photoresist 5.

Furthermore, an additional insulating film or electrode layer may be formed below the light shield section 4 as well. Nonetheless, any additional electrode layer formed below the light shield section 4 must not overlap with the area where the hole pattern 6 is to be formed, or if the additional electrode layer does overlap with the area where the hole pattern 6 is to be formed, it must have a smaller size area than the light shield section 4.

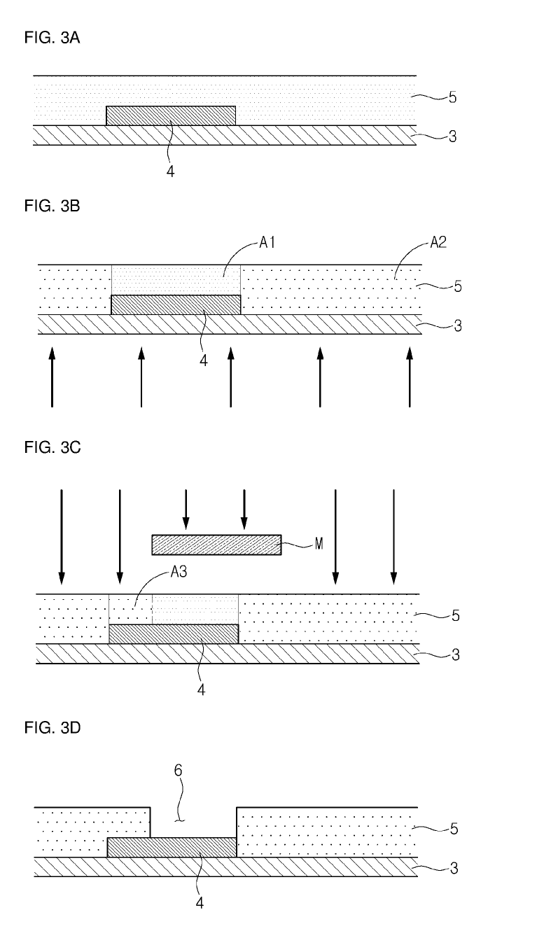

In an embodiment of the present disclosure, the upward light exposing step may be performed prior to the downward light exposing step, as illustrated in FIGS. 3A-3D.

More specifically, in the case of performing the upward light exposing step first, as illustrated in FIG. 3B, the area of the photoresist 5 that overlaps with the light shield section 4 (A1: non-hardened area) remains non-hardened, while the remaining area (A2: hardened area) is exposed to light and is thus hardened.

Then, when the downward light exposing step is performed as illustrated in FIG. 3C, of the area that had been maintained in a non-hardened state at the upward light exposing step, the area A3 that does not overlap with the mask is additionally hardened.

Then, when the photoresist is developed at this state, the non-hardened photoresist will be removed, and a hole pattern 6 will be formed above the light shield section, as illustrated in FIG. 3D.

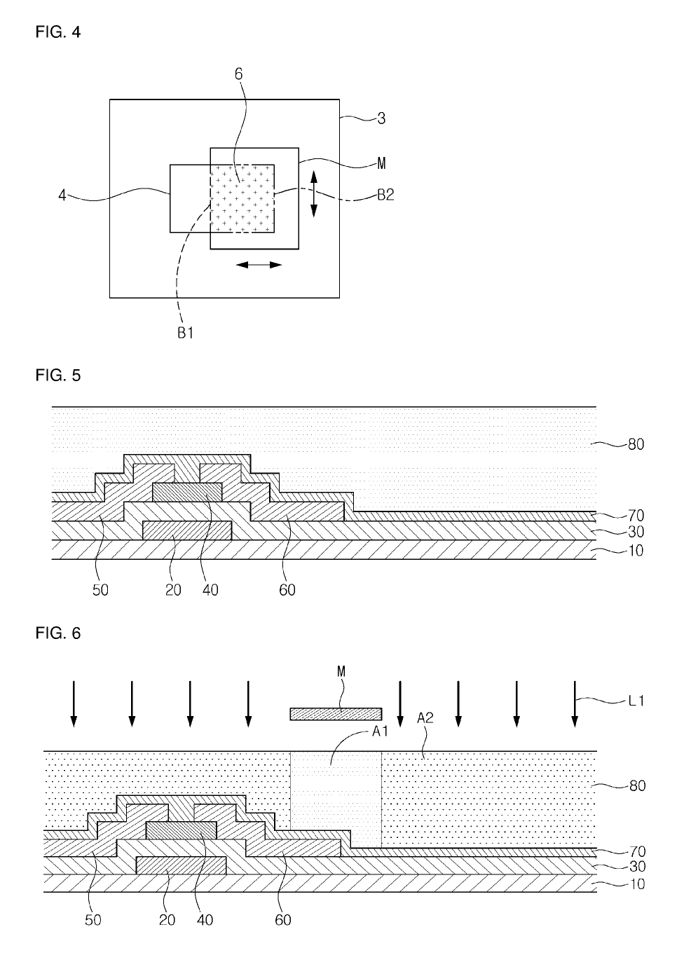

In either case, that is, regardless of whether the method of FIG. 2 is used or the method of FIG. 3 is used to form a hole pattern, the hole pattern 6 will be formed on the area where the light shield section 4 and the mask M overlaps each other, as illustrated in FIG. 4.

More specifically, when a hole pattern is formed according to an embodiment of the present disclosure, a partial boundary B1 of the hole pattern 6 will be determined within the light shield section 4 according to the boundary of the mark M at the downward light exposing step, and the rest of the boundary B2 of the hole pattern 6 will be determined within the mask M according to the boundary of the light shield section 4 at the upward light exposing step.

Therefore, when using a hole pattern forming method according to an embodiment of the present disclosure, by just positioning a mask M to overlap with a light shield section 4, it is possible to prevent the hole pattern from being formed horizontally beyond the light shield section.

Hereinafter, a method for manufacturing a TFT display according to an embodiment of the present disclosure will be explained in detail.

The method for manufacturing a TFT display according to an embodiment of the present disclosure is characterized to use the hole pattern forming method explained hereinabove in forming a hole pattern. Therefore, hereinafter, the method for manufacturing a TFT display according to an embodiment of the present disclosure will be explained with a main focus on the method for forming a via hole pattern during a TFT display manufacturing process.

FIGS. 5 to 9 are views illustrating a TFT display manufacturing method according to an embodiment of the present disclosure.

FIG. 5 is a cross-sectional view of a TFT formed on a unit pixel area of a TFT display.

In order to form a TFT on a unit pixel area of a TFT display, a gate electrode 20 is formed above a substrate 10, and then followed by a gate insulating film 30, active layer 40, source electrode 50/drain electrode 60, and TFT insulating film 70, formed sequentially. Such a TFT manufacturing method is well known to those skilled in the art, and thus detailed explanation will be omitted so as not to obscure the essence of the present disclosure.

In order to electrically connect the drain electrode 60 and a pixel electrode that will be formed above the TFT in a TFT display, a portion of the TFT insulating film 70 is etched to form a via hole above the drain electrode.

For this purpose, a photoresist 80 is applied above the TFT insulating film, as illustrated in FIG. 5.

Herein, preferably, the photoresist used may be a negative type photoresist.

After applying the photoresist, a mask M is positioned above the drain electrode, and then the photoresist 80 is exposed to light L1 being emitted downwards from above substrate 10 as illustrated in FIG. 6 (downward light exposing step).

At this downward light exposing step, the photoresist 80 in the area A2 (hardened area) besides the area A1 (non-hardened area) below the mask is exposed to the light L1 and is thus hardened.

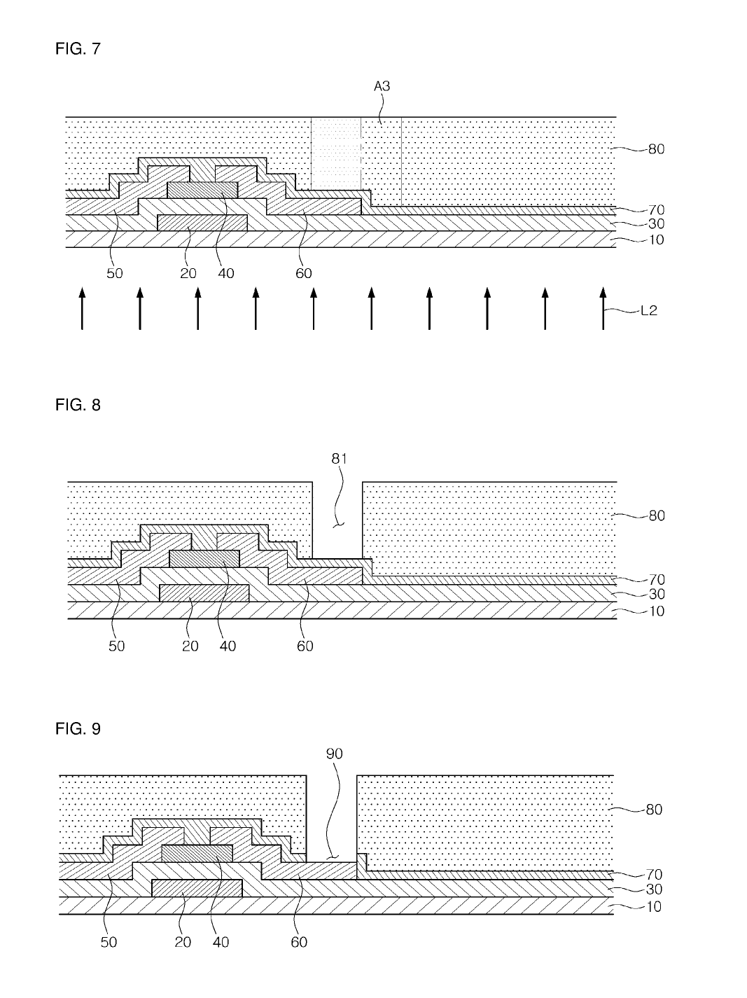

Next, as illustrated in FIG. 7, the photoresist 80 is exposed to light L2 being emitted upwards from below the substrate 10 (upward light exposing step).

At the upward light exposing step, unlike the first light exposing step, a mask is not positioned below the substrate. However, since the TFT below the photoresists 80 shields against the light L2, of the non-hardened area A1, only the photoresist 80 in the area (A3: additionally hardened area) not shielded from the light L2 by the TFT is exposed to the light L2 and is thus hardened.

After the aforementioned upward and downward light exposing steps, when the photoresist is developed, only the area that had not been exposed to light at both the upward light exposing step and downward light exposing step will be removed and a hole pattern 81 will be completed, as illustrated in FIG. 8.

Furthermore, as illustrated in FIG. 9, by etching the TFT insulating film 70 below the hole pattern 81 formed, it is possible to easily form a via hole 90 that does not go beyond the drain electrode area above the drain electrode 60 of the TFT.

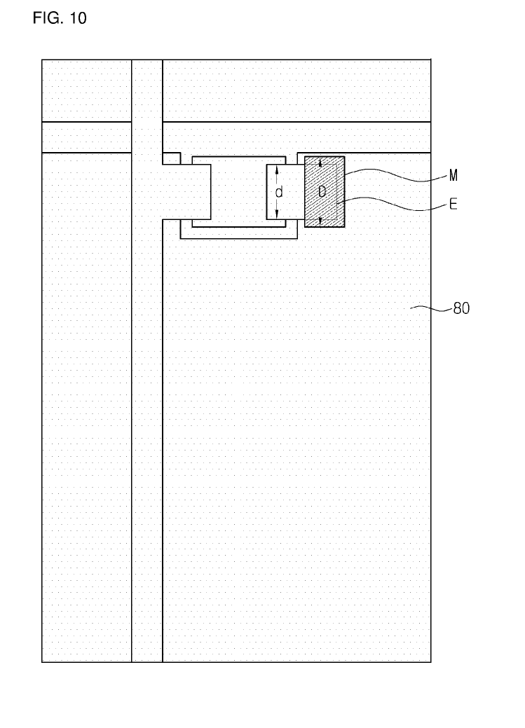

Hereinafter, the aforementioned method for forming a TFT display according to an embodiment of the present disclosure will be explained once again with reference to the plane views illustrated in FIGS. 10 to 13.

After the photoresist 80 is applied above the substrate where the TFT and TFT insulating film are formed, a mask M is positioned to overlap with the drain electrode, as illustrated in FIG. 10.

Herein, it is desirable that the mask M does not horizontally overlap with the gate electrode and gate line adjacent to the drain electrode.

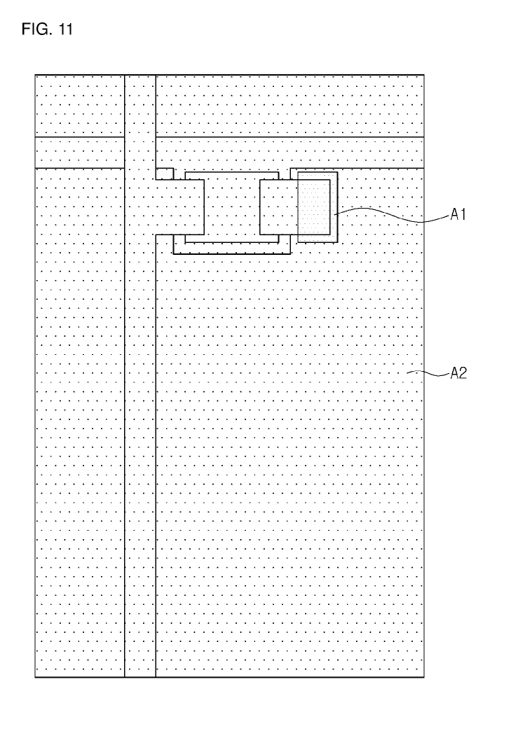

Furthermore, when the photoresist is exposed to light L1 being emitted downwards from above the substrate 10, only the area shadowed by the mask is maintained in a non-hardened state A1, and the remaining area is exposed to the light L1 and is thus hardened, as illustrated in FIG. 11 (downward light exposing step).

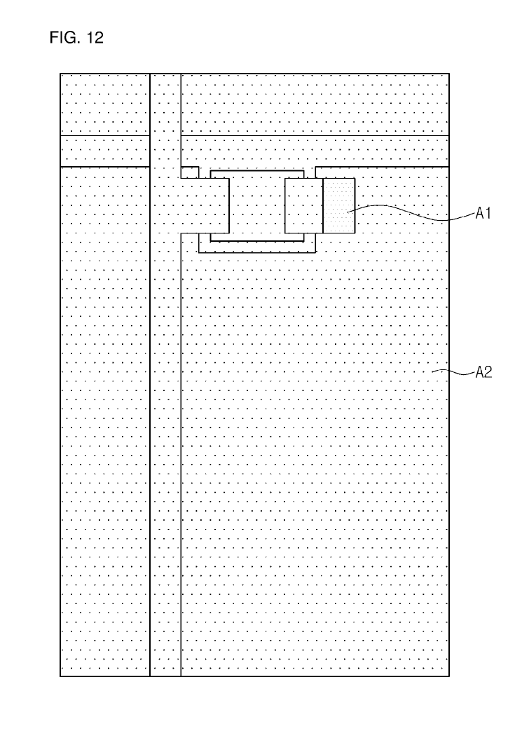

Then, when the photoresist is exposed to light L2 being emitted upwards from below the substrate 10, of the area that had been maintained in a non-hardened state at the downward light exposing step, the area not overlapping with the drain electrode is exposed to the light L2 and is thus hardened, and only the area overlapping with the drain electrode is maintained in a non-hardened state A1, as illustrated in FIG. 12 (upward light exposing step).

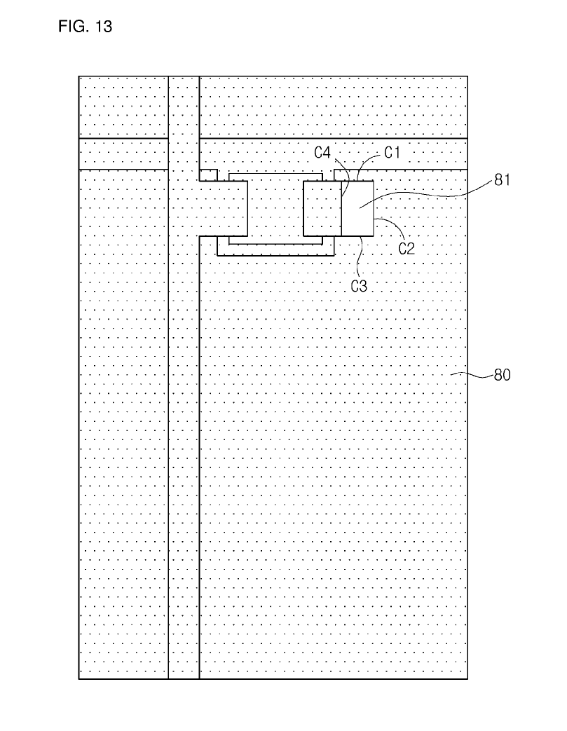

Furthermore, when the non-hardened photoresist is removed, a hole pattern will be formed only in the area horizontally overlapping with the drain electrode, as illustrated in FIG. 13.

According to the via hole forming method of the present disclosure, by the aforementioned upward and downward light exposing steps, only the photoresist in the area where the mask and the drain electrode horizontally overlap with each other is maintained in a non-hardened state. Therefore, by just positioning a mask to overlap with the drain electrode, it is possible to prevent the hole pattern from being formed horizontally beyond the drain electrode.

Furthermore, by positioning a mask M having a width D that is bigger than the width d of the drain electrode, as illustrated in FIG. 10, such that, of the data line direction boundaries of the drain electrode, the boundary E that is not above the gate electrode 20 is horizontally positioned within the mask, it is possible to control such that, of the boundaries of the hole pattern, the boundaries C1, C2, C3 not horizontally located within the drain electrode exactly correspond to the boundaries of the drain electrode, as illustrated in FIG. 13.

Just as in the hole pattern forming method according to an embodiment of the present disclosure, the TFT display manufacturing method according to an embodiment of the present disclosure may also perform the upward light exposing step before the downward light exposing step.

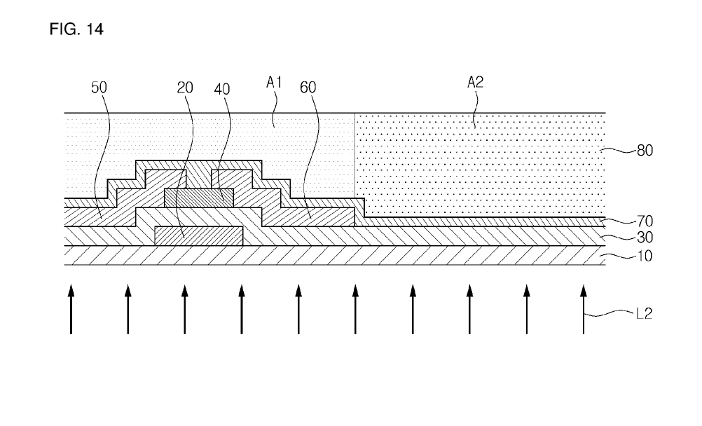

More specifically, as illustrated in FIG. 14, the photoresist 80 is first exposed to light L2 being emitted upwards from below the substrate (upward light exposing step).

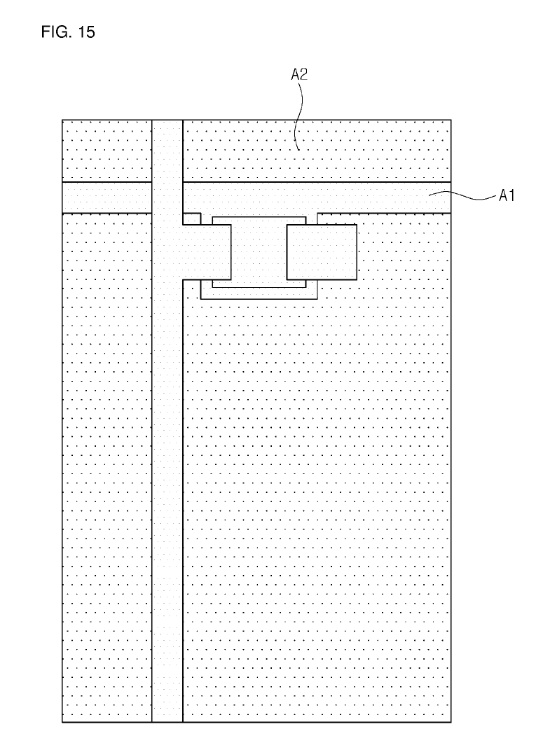

By this upward light exposing step, only the photoresist above the gate line, data line, and the TFT is maintained in a state not exposed to light, as illustrated in FIG. 15.

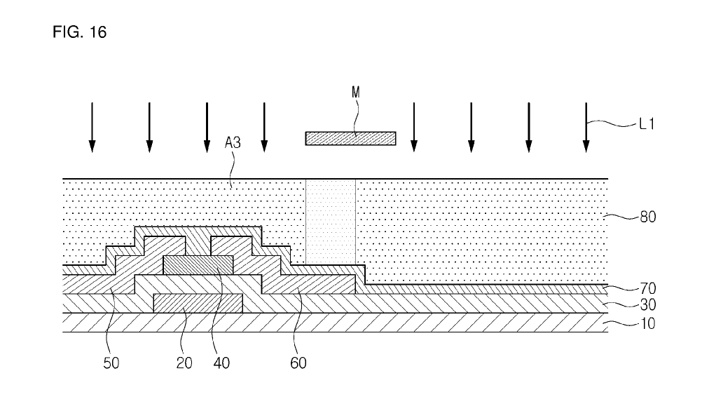

Next, as illustrated in FIG. 16, a mask is positioned above the drain electrode, and the photoresist 80 is exposed to light L1 being emitted downwards from above the substrate (downward light exposing step).

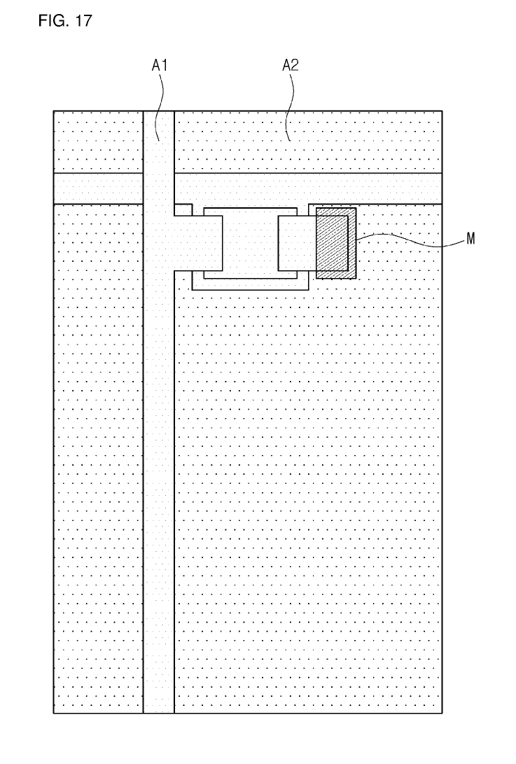

As aforementioned, it is desirable that the mask M is positioned such that it horizontally overlaps with the drain electrode but not with the gate electrode and gate line adjacent to the drain electrode (see FIG. 17).

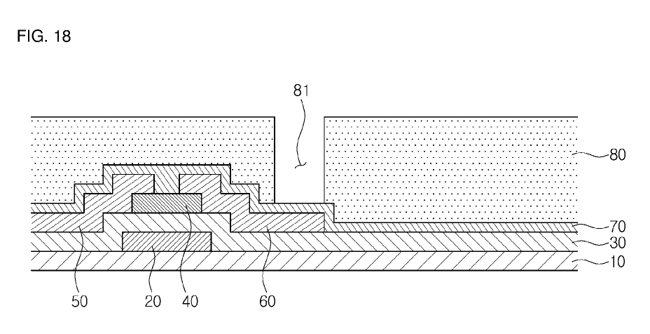

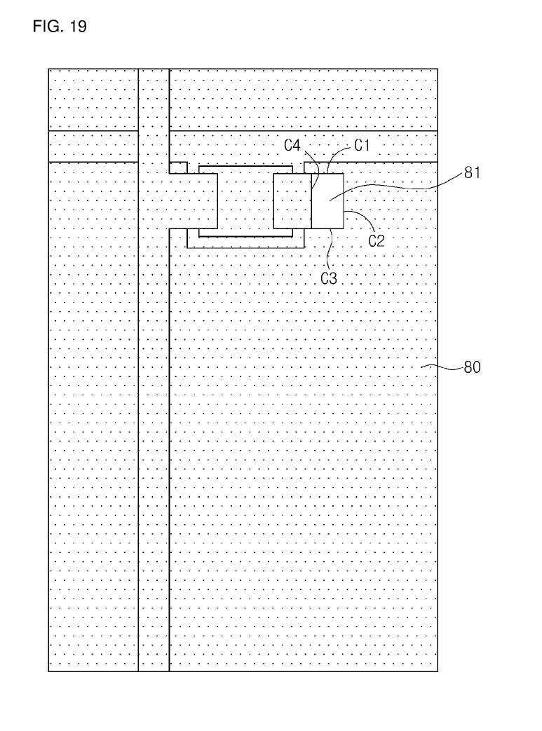

By such a light exposing step, only the photoresist in the area where the mask M and the drain electrode 60 horizontally overlaps with each other is maintained in a state not exposed to light, and is thus removed by a developing solution (see FIGS. 18 and 19).

The order of performing the upward light exposing step and the downward light exposing step of the method for manufacturing a TFT display according to an embodiment of the present disclosure may be the other way round.

Furthermore, regardless of the order of performing the upward light exposing step and the downward light exposing step, by just positioning the mask to horizontally overlap with the drain electrode at the downward light exposing step, it is possible to control so that the hole pattern formed above the drain electrode does not horizontally go beyond the drain electrode.

Furthermore, since it is possible to control the boundaries C1˜C3 of the hole pattern that are not within the drain electrode to exactly correspond to the boundaries of the drain electrode, when using the via hole forming method of the present disclosure, there is no need to form the drain electrode bigger, in consideration of the error range of the via hole pattern. Therefore, it is possible to minimize the size of the drain electrode, thereby maximizing the opening rate and transmission rate of the TFT display.

Furthermore, the remaining boundary C4 of the hole pattern that has not been controlled exactly due to the alignment error of the mask M is a boundary located within the drain electrode. Therefore, even if the position of the boundary C4 is not controlled exactly, there will be no effect on the opening rate and transmission rate of the TFT display.

While this disclosure includes specific embodiments of a method for forming a hole pattern and a method for manufacturing a TFT display using the same according to various embodiments of the present disclosure, it will be apparent to one of ordinary skill in the art that various changes in form and details may be made in these embodiments without departing from the spirit and scope of the claims and their equivalents.

What is claimed is:

1. A method for manufacturing a TFT display, the method comprising:
forming a TFT above a substrate;
applying a photoresist above the TFT;
downward light exposing which comprises positioning a mask above the TFT and then exposing the photoresist to light being emitted downwards from above the substrate;
upward light exposing which comprises exposing the photoresist to light being emitted upwards from below the substrate; and
forming a hole pattern by removing the photoresist not exposed to light at the downward light exposing and upward light exposing.

2. The method of claim 1,
wherein the mask is positioned such that it horizontally overlaps with a portion of a drain electrode of the TFT.

3. The method of claim 2,
wherein the mask is positioned such that it horizontally does not overlap with a gate electrode nor gate line.

4. The method of claim 3,
wherein the mask is positioned such that, of data line direction boundaries of the drain electrode, a boundary not located above the gate electrode is horizontally within the mask.

5. The method of claim 2,
further comprising:
forming a TFT insulating film above the TFT after the forming of a TFT and before the applying of a photoresist; and
forming a via hole by etching the TFT insulating film exposed below the hole pattern after the forming of a hole pattern.

6. The method of claim 3,
further comprising:
forming a TFT insulating film above the TFT after the forming of a TFT and before the applying of a photoresist; and
forming a via hole by etching the TFT insulating film exposed below the hole pattern after the forming of a hole pattern.

7. The method of claim 4,
further comprising:
forming a TFT insulating film above the TFT after the forming of a TFT and before the applying of a photoresist; and
forming a via hole by etching the TFT insulating film exposed below the hole pattern after the forming of a hole pattern.

8. The method of claim 1,
wherein the photoresist is a negative type photoresist.

9. The method of claim 1,
wherein the upward light exposing is performed before the downward light exposing.

10. The method of claim 1,
wherein the downward light exposing is performed before the upward light exposing.

11. The method of claim 1,
wherein the upward light exposing and the downward light exposing are performed simultaneously.

12. A method for forming a hole pattern, the method comprising:
forming a light shield section above a substrate;
applying a photoresist above the light shield section;
downward light exposing which comprises positioning a mask above the light shield section and then exposing the photoresist to light being emitted downwards from above the substrate;
upward light exposing which comprises exposing the photoresist to light being emitted upwards from below the substrate; and
removing the photoresist not exposed to light at the downward light exposing and upward light exposing.

13. The method of claim 12,
wherein the mask is positioned such that a partial boundary of the light shield section is horizontally within the mask.

14. The method of claim 12,
wherein the photoresist is a negative type photoresist.

15. The method of claim 12,
wherein the upward light exposing is performed before the downward light exposing.

16. The method of claim 12,
wherein the downward light exposing is performed before the upward light exposing.

17. The method of claim 12,
wherein the upward light exposing and the downward light exposing are performed simultaneously.
